(19) United States
(12) Patent Application Publication
(10) Pub. No.: US 2022/0244647 A1
(43) Pub. Date: Aug. 4, 2022

(54) INTEGRATED CIRCUIT STRUCTURE FORMATION METHOD

(71) Applicant: CHANGXIN MEMORY TECHNOLOGIES, INC., Hefei City (CN)

(72) Inventor: SUNGJIN KIM, Hefei City (CN)

(21) Appl. No.: 17/456,053

(22) Filed: Nov. 22, 2021

Related U.S. Application Data
(63) Continuation of application No. PCT/CN2021/110880, filed on Aug. 5, 2021.

(30) Foreign Application Priority Data
Jan. 29, 2021 (CN) 202110128716.X

(51) Int. Cl. G03F 7/20

(52) U.S. Cl. CPC G03F 7/2024

(57) ABSTRACT

Embodiments of the present application provide an integrated circuit structure formation method, including: providing a first pattern and a to-be-corrected pattern, the first pattern including a first subpattern and a second subpattern spaced apart, the to-be-corrected pattern being located between the first subpattern and the second subpattern, and a preset horizontal distance being provided between the first pattern and the to-be-corrected pattern; providing a trim mask, the trim mask having a preset region, in a plane including the to-be-corrected pattern, a first orthographic projection of the preset region overlapping with the to-be-corrected pattern, a second orthographic projection being located on one side of the to-be-corrected pattern, and a horizontal length being greater than or equal to twice the preset horizontal distance; and performing an exposure process through the trim mask to form a target pattern. The embodiments of the present application facilitate accurate trimming of the to-be-corrected pattern.

### CROSS-REFERENCE TO RELATED APPLICATIONS

This application is a continuation application of International Patent Application No. PCT/CN2021/110880, filed on Aug. 5, 2021, which claims priority to Chinese Patent Application No. 202110128716.X, filed with the Chinese Patent Office on Jan. 29, 2021 and entitled “INTEGRATED CIRCUIT STRUCTURE FORMATION METHOD.” International Patent Application No. PCT/CN2021/110880 and Chinese Patent Application No. 202110128716.X are incorporated herein by reference in their entireties.

### TECHNICAL FIELD

The present application relates to the field of semiconductors, and in particular, to an integrated circuit structure formation method.

### BACKGROUND

With an increasingly-miniaturized integrated circuit, problems caused by an optical proximity effect are more and more serious. When two separate components are too close to each other, the optical proximity effect may make them closer to each other and even bridged. In order to solve this problem, a double patterning technology (DPT) is introduced, and different components at adjacent positions are formed through two masks.

However, after a double patterning process, sometimes certain particular patterns are required to be trimmed to meet particular electrical requirements. Therefore, how to realize accurate trimming of particular patterns has become an urgent problem to be solved currently.

### SUMMARY

Embodiments of the present application provide an integrated circuit structure formation method, which facilitates accurate trimming of a to-be-corrected pattern.

The embodiments of the present application provide an integrated circuit structure formation method, including: providing a first pattern and a to-be-corrected pattern, the first pattern including a first subpattern and a second subpattern spaced apart, the to-be-corrected pattern being located between the first subpattern and the second subpattern, and a preset horizontal distance being provided between the first pattern and the to-be-corrected pattern; providing a trim mask, the trim mask having a preset region, in a plane including the to-be-corrected pattern, a first orthographic projection of the preset region overlapping with the to-be-corrected pattern, and a second orthographic projection being located on one side of the to-be-corrected pattern and having a horizontal length greater than or equal to twice the preset horizontal distance; and performing an exposure process through the trim mask to form a target pattern.

### BRIEF DESCRIPTION OF DRAWINGS

One or more embodiments are exemplarily described by using figures that are corresponding thereto in the accompanying drawings. Unless otherwise particularly stated, the figures in the accompanying drawings do not constitute a scale limitation.

FIG. 1 is a schematic layout diagram of pattern decomposition;

FIG. 2 to FIG. 8 are schematic structural diagrams corresponding to an integrated circuit structure formation method;

FIG. 9 is a schematic layout diagram of components;

FIG. 10 to FIG. 13 are schematic layout diagrams of pattern decomposition according to an embodiment of the present application;

FIG. 14 is a schematic structural diagram corresponding to an integrated circuit structure formation method according to an embodiment of the present application; and

FIG. 15 is a schematic layout diagram of components according to an embodiment of the present application.

### DESCRIPTION OF EMBODIMENTS

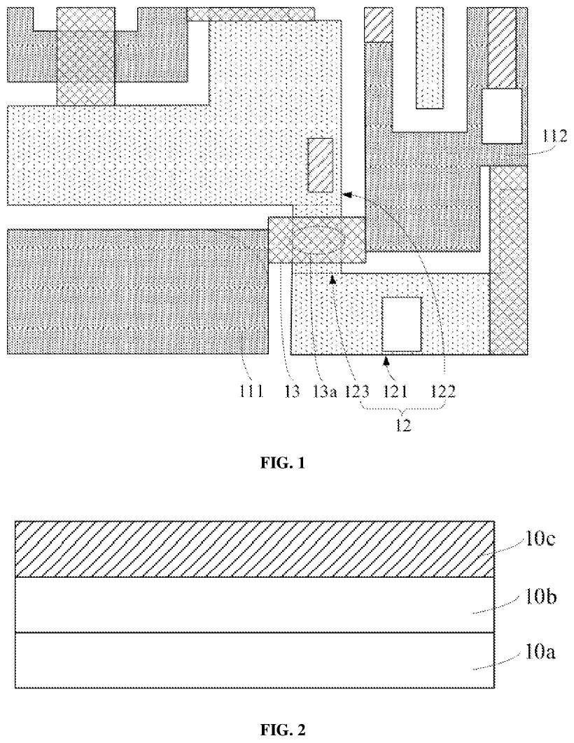

Referring to FIG. 1, after pattern decomposition, a schematic layout diagram of pattern decomposition is obtained. The schematic layout diagram of pattern decomposition corresponds to a schematic layout diagram of desired components, for illustrating current layout of the components and a mask for use in further processing. Specifically, a first pattern (not marked) and a to-be-corrected pattern 12 refer to current layout of components. A trim mask 13 refers to a photomask for further trimming. A trim pattern of the trim mask 13 refers to a target trim region.

In an optional embodiment, the first pattern (not marked) includes a first subpattern 111 and a second subpattern 112 spaced apart. The to-be-corrected pattern 12 includes a third subpattern 121, a four subpattern 122 and a connection pattern 123 that plays a connection role. The to-be-corrected pattern 12 is located between the first subpattern 111 and the second subpattern 112. A preset horizontal distance is provided between the first pattern and the to-be-corrected pattern 12. When the preset horizontal distance is less than a minimum critical dimension of an exposure machine, a double patterning technology is needed so as to ensure effective formation of the first pattern and the to-be-corrected pattern 12.

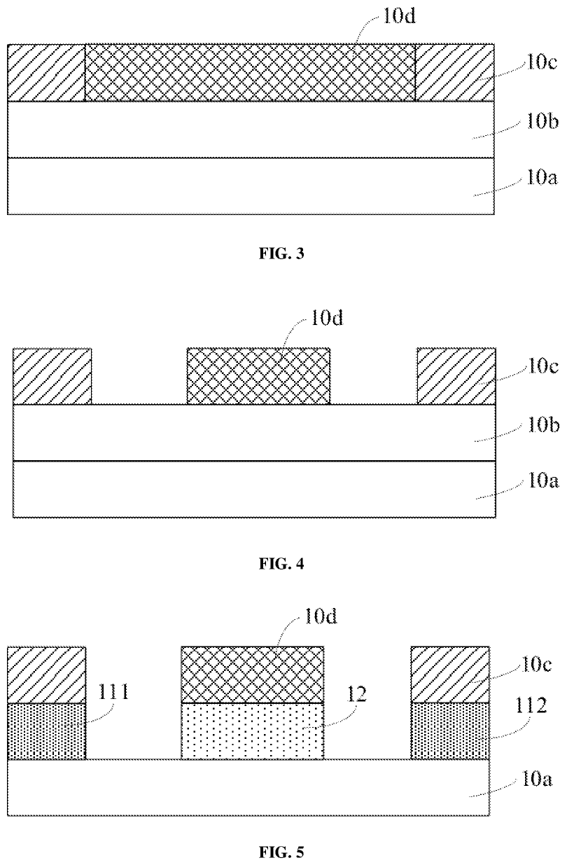

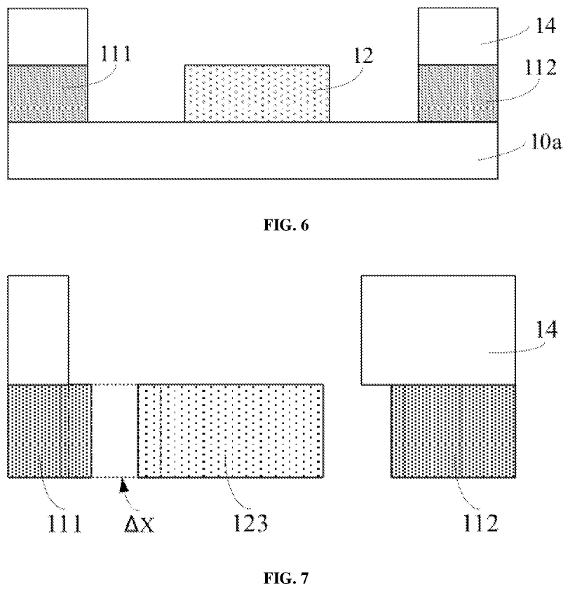

The double patterning technology involves the following general steps: referring to FIG. 2, forming a substrate 10a, a target layer 10b and a first photoresist layer 10c sequentially stacked; referring to FIG. 3, providing a first photomask corresponding to the first pattern, exposing the first photoresist layer 10c through the first photomask, performing development to obtain a first photoetch pattern, and filling the first photoetch pattern with a second photoresist layer 10d; referring to FIG. 4, providing a second photomask corresponding to the to-be-corrected pattern 12, and exposing the second photoresist layer 10d through the second photomask; obtaining a second photoetch pattern after development; and referring to FIG. 5, patterned etching is performed on the target layer 10b through the second photoetch pattern to form the first pattern and the to-be-corrected pattern 12. However, the third subpattern 121 and the four subpattern 122 in the to-be-corrected pattern 12 are required to be electrically isolated; therefore, referring to FIG. 6, after the first pattern and the to-be-corrected pattern 12 are formed, the first photoresist layer 10c and the second photoresist layer 10d may be removed to form a third photoresist layer 14, the third photoresist layer 14 is exposed through the trim mask 13, a third photoetch pattern is obtained after development, and an etching process is performed through the third photoetch pattern to trim the connection pattern 123, so that the third subpattern 121 and the four subpattern 122 are separated and electrically isolated from each other.

In a plane including the to-be-corrected pattern 12, an orthographic projection of the trim mask 13 overlaps partially with the connection pattern 123. An overlap region is an ideal trim region. The third subpattern 121 may be effectively electrically isolated from the four subpattern 122 by removing the connection pattern 123 in the trim region. In addition, in order to prevent the influence of the exposure performed through the trim mask 13 on the formation of the first pattern, the orthographic projection of the trim mask 13 is located between the first subpattern 111 and the second subpattern 112; that is, the orthographic projection of the trim mask 13 does not overlap with an orthographic projection of the first pattern. A maximum horizontal length of the trim mask 13 is equal to a horizontal distance between the first subpattern 111 and the second subpattern 112.

However, due to the influence of an Optical Proximity Effect (OPE), an actual exposure region of a photomask may be distorted relative to an ideal exposure region, which may lead to distortion of an actual trim region relative to the ideal trim region. Types of the distortion include rounding of the corner, line shortening and pattern contraction. Specifically, a right angle of the first subpattern 111 is distorted to a rounding of the corner, the ideal trim region of the trim mask 13 is of a rectangle, and the actual trim region is of an ellipse 13a. A horizontal length and a vertical width of the ellipse 13a are both less than those of the rectangle. As a result, the trim mask 13 cannot trim the connection pattern 123 effectively, and then the third subpattern 121 and the four subpattern 122 cannot be effectively isolated.

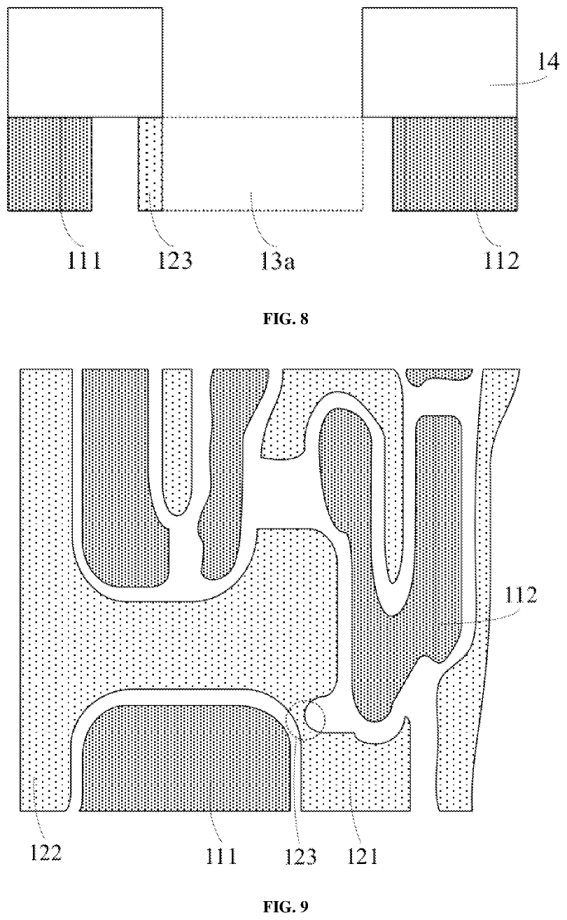

Referring to FIG. 6, ideally, the third photoresist layer 14 above the connection pattern 123 can be effectively exposed, after the third photoresist layer 14 is exposed and developed, patterned etching performed through the third photoresist layer 14 may effectively truncate the connection pattern 123, and the to-be-corrected pattern 12 is divided into two separate parts. Referring to FIG. 7 to FIG. 9, affected by the optical proximity effect, part of the photoresist above the connection pattern 123 is not exposed effectively due to process offset ΔX caused by the distortion, patterned etching performed through the third photoresist layer 14 cannot effectively truncate the connection pattern 123, and the third subpattern 121 and the four subpattern 122 are still bridged through the connection pattern 123.

In addition, in some cases, the contracted ellipse 13a can still effectively expose the photoresist layer corresponding to the connection pattern 123. However, since the vertical width at two ends of the ellipse 13a is small in a horizontal direction, a minimum vertical width of the photoresist layer exposed is also small. As a result, during the patterned etching, the two parts of the connection pattern 123 separated by trimming attract each other due to their proximity, leading to an undesired electrical short circuit connection.

The embodiment of the present application provides an integrated circuit structure formation method, in which a horizontal length of a second orthographic projection is greater than or equal to twice the preset horizontal distance, helping accurately trim the to-be-corrected pattern overlapping with the orthographic projection of the preset region to form a target pattern meeting requirements in a case where a trim region corresponding to the preset region contracts.

In order to make the objectives, technical solutions and advantages of the embodiments of the present application clearer, various embodiments of the present application will be described below in detail with reference to the drawings. However, those of ordinary skill in the art may understand that, in the embodiments of the present application, numerous technical details are set forth in order to enable a reader to better understand the present application. However, the technical solutions claimed in the present application can be implemented without these technical details and various changes and modifications based on the embodiments below.

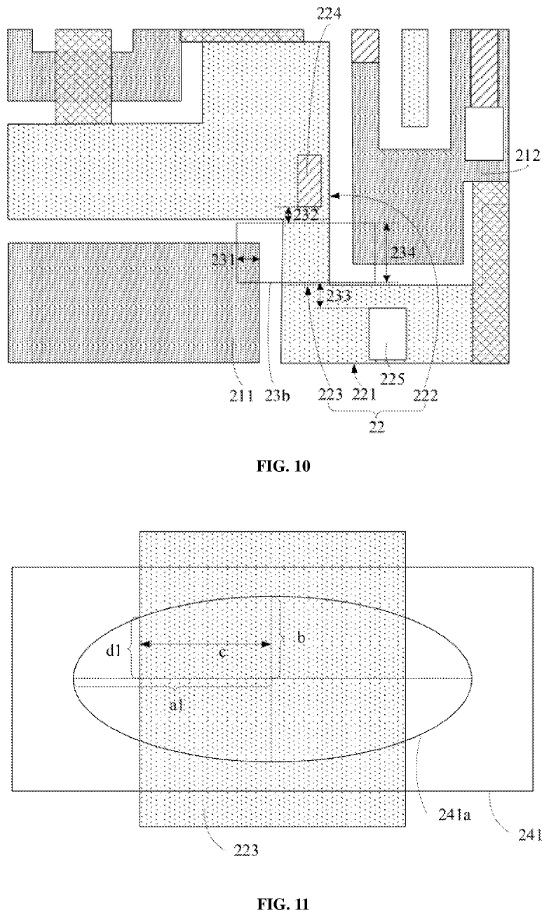

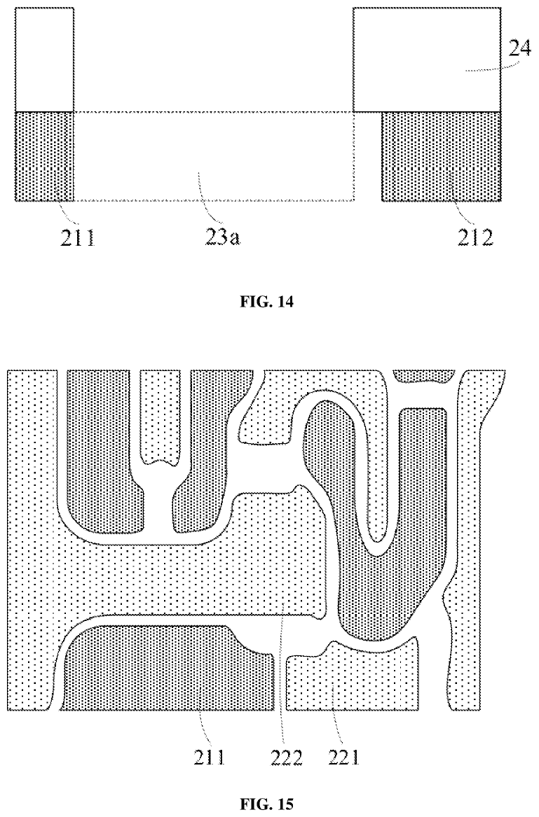

FIG. 10 to FIG. 13 are schematic layout diagrams of pattern decomposition according to an embodiment of the present application; FIG. 14 is a schematic structural diagram corresponding to an integrated circuit structure formation method according to an embodiment of the present application; and FIG. 15 is a schematic layout diagram of components according to an embodiment of the present application. In the present embodiment, the step of forming a target pattern includes the following steps.

Referring to FIG. 10, a first pattern (not marked) and a to-be-corrected pattern 22 are provided.

In an optional embodiment, a preset horizontal distance is provided between the first pattern and the to-be-corrected pattern 22. Since the preset horizontal distance is less than a minimum critical dimension of an exposure machine, a double patterning technology is needed to form the first pattern and the to-be-corrected pattern 22, which prevents bridging caused by mutual attraction between the first pattern and the to-be-corrected pattern 22 during the formation and ensures separation between the first pattern and the to-be-corrected pattern 22. Specific process steps of forming the first pattern and the to-be-corrected pattern 22 are as follows.

A first photomask, a substrate, and a target layer and a first positive photoresist layer sequentially stacked on a surface of the substrate are provided, and a first exposure process is performed on the first positive photoresist layer through the first photomask. A first development process is performed to form a first photoetch pattern, the first photoetch pattern being configured to etch the target layer to form the first pattern. A second positive photoresist layer is formed to fill the first photoetch pattern. A second photomask is provided, and a second exposure process is performed on the second positive photoresist layer through the second photomask. A second development process is performed to form a second photoetch pattern, the second photoetch pattern being configured to etch the target layer to form the to-be-corrected pattern 22. Patterned etching is performed on the target layer through the second photoetch pattern to form the first pattern and the to-be-corrected pattern 22.

It is to be noted that, the present embodiment is illustrated with an example in which the photoresist layer is made only of a positive photoresist. In fact, a photoresist material may also be a negative photoresist. In addition, the first photoetch pattern and the second photoetch pattern may be formed respectively by using different types of photoresists. For example, the first photoetch pattern is formed of a positive photoresist, and the second photoetch pattern is formed of a negative photoresist.

In an optional embodiment, after the first pattern and the to-be-corrected pattern 22 are formed, a trim mask is provided. The trim mask has a preset region. In a plane including the to-be-corrected pattern 22, an orthographic projection of the preset region is an ideal trim region of the trim mask.

An actual form of the “preset region” is related to a type of a to-be-exposed photoresist. When the photoresist is a positive photoresist, the preset region is a patterned opening of the trim mask. When the photoresist is a negative photoresist, the preset region is in a shape of the trim mask. The present embodiment is specifically illustrated with an example in which the to-be-exposed photoresist is a positive photoresist and the preset region is a patterned opening.

In an optional embodiment, after the first pattern and the to-be-corrected pattern 22 are formed, the first positive photoresist layer and the second positive photoresist layer are removed, a third positive photoresist layer is formed on the to-be-corrected pattern 22, the third positive photoresist layer is exposed through the trim mask, and the to-be-corrected pattern 22 is trimmed through the patterned opening formed after development, so as to form a target pattern. In other embodiments, the second positive photoresist layer may also be further exposed through the trim mask, and the to-be-corrected pattern is trimmed through the second positive photoresist layer further patterned, so as to form the target pattern.

It is to be noted that, in another optional embodiment, if the second positive photoresist layer is selected for further exposure, during the formation of the to-be-corrected pattern, specifically, after the second development process, the second positive photoresist layer may not be hard-baked but be directly patterned and etched. This helps reduce the difficulty in subsequently exposing the second positive photoresist layer by using the trim mask, and helps shorten the exposure time.

In an optional embodiment, in order to ensure that the contracted actual trim region can effectively truncate the connection pattern 223 under the influence of the optical proximity effect, dimension parameters of an effective range 23b of the “preset region” are required to be limited. The dimension parameters include a horizontal length and a vertical width. When a horizontal length of the contracted actual trim region is greater than that of the connection pattern 223, the contracted actual trim region can effectively truncate the connection pattern 223 in an ideal state. When an actual vertical width after contraction is greater, two parts of the connection pattern 223 separated from each other may not attract each other due to their proximity to be then bridged during the patterned etching.

In an optional embodiment, in the plane including the to-be-corrected pattern 22, a first orthographic projection of the preset region overlaps with the to-be-corrected pattern 22, and a second orthographic projection is located on one side of the to-be-corrected pattern 22 and has a horizontal length greater than or equal to twice the preset horizontal distance. The first orthographic projection and the second orthographic projection are two parts of the orthographic projection of the preset region. The horizontal length of the second orthographic projection is greater than or equal to twice the preset horizontal distance, and a distance between the first subpattern 211 and the to-be-corrected pattern 22 is the preset horizontal distance; therefore, in a plane including the first pattern, the second orthographic projection overlaps partially with the first subpattern 211, and a horizontal length of an overlap region is greater than or equal to a preset horizontal spacing.

Herein, the horizontal length of the overlap region is recorded as a first horizontal length 231. When the first horizontal length is greater than the preset horizontal distance, it helps ensure that a maximum horizontal length of the contracted actual trim region is greater than a horizontal length of the connection pattern 223, so as to truncate the connection pattern 223 ideally, thereby ensuring electrical isolation between the third subpattern 221 and the fourth subpattern 222.

It is to be noted that, only a horizontal length of an orthographic projection located on one side of the connection pattern 223 is limited in the present embodiment. In fact, a horizontal length of an orthographic projection located on the other opposite side of the connection pattern 223 may also be limited in a same manner, so as to ensure that the contracted actual trim region can effectively truncate two opposite sides of the connection pattern 223 and prevent truncation of only one side. In addition, under the influence of the optical proximity effect, when only one side cannot be effectively truncated, only the horizontal length of the orthographic projection located on one side of the connection pattern 223 may be limited, so as to truncate the side on which bridging is maintained.

Herein, the vertical width of the preset region is recorded as a first vertical width 234. Parameter setting of the first vertical width 234 is related to parameter setting of the horizontal length of the second orthographic projection. Specifically, the greater a ratio of the horizontal length of the second orthographic projection to the horizontal length of the connection pattern 223, the greater the horizontal length of the effective range 23b, and the greater the horizontal length of the contracted ellipse in a case where a contraction ratio is constant. Since a position of the side of the connection pattern 223 is unchanged, the side of the connection pattern 223 is relatively closer to a minor axis of the ellipse after the horizontal length of the ellipse increases. Further, when a vertical width of the minor axis is unchanged, since the side of the connection pattern 223 is closer to the minor axis, the vertical width of the ellipse on a straight line where the side is located increases.

According to the above analysis, when the horizontal length of the ellipse increases, the vertical width of the minor axis, that is, the first vertical width 234 prior to the contraction, can be reduced if the vertical width of the ellipse on the straight line where the side is located is unchanged. That is, the greater the ratio, the greater the horizontal length of the effective range 23b, and the smaller a minimum value of the first vertical width 234. The less the ratio, the less the horizontal length of the effective range 23b, and the larger the minimum value of the first vertical width 234.

Detailed comparative descriptions are provided below with reference to the drawings. It is to be noted that, values in the drawings are used as examples only, and do not provide reference for actual values.

Referring to FIG. 11, assuming that the preset region is a first region 241, the first region 241 is distorted to form a first ellipse 241a. The first ellipse 241a has a semi-major axis with a length of a1 and a semi-minor axis with a length of b. The value of a1 is determined by a horizontal length of the first region 241, and the value of b is determined by a vertical width of the first region 241. The connection pattern 223 overlaps with an orthographic projection of the first region 241, a horizontal distance between one side of the connection pattern 223 and a minor axis of the first ellipse 241a is c, and on a straight line where the side is located, a vertical width of the first ellipse 241a is twice d1.

It may be determined that, when the horizontal length and the vertical width of the first region 241 are unchanged, for the first ellipse 241a after distortion and contraction, the length of the semi-major axis is always a1, and the length of the semi-minor axis is always b.

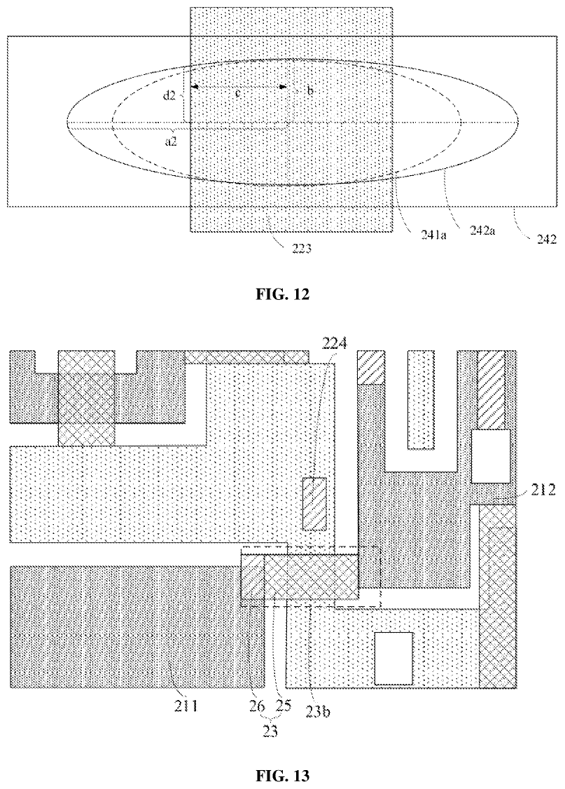

Referring simultaneously to FIG. 12, assuming that the preset region is adjusted to a second region 242, compared with the first region 241, the second region 242 has a larger horizontal length and a constant vertical width, a second ellipse 242a after distortion and contraction of the second region 242 has a semi-major axis with a length of a2 and a semi-minor axis with a length of b. Since the second region 242 has a larger horizontal length, a2 is greater than a1. Since the position of the connection pattern 223 is unchanged, the horizontal distance between the side of the connection pattern 223 and the minor axis of the first ellipse 241a is still c. When the length of the semi-major axis increases, it may be considered that the side of the connection pattern 223 is relatively closer to the minor axis. Specifically, c/a1 is greater than c/a2. Correspondingly, on the straight line where the side of the connection pattern 223 is located, half of the vertical width of the second ellipse 242a is closer to the length b of the semi-minor axis; therefore, d2 is greater than d1.

According to the above analysis, in a case where the vertical width is unchanged, a horizontal increase in the preset region may lead to an increase in the vertical width of the ellipse on the straight line where the side of the connection pattern 223 is located, two truncated parts of the to-be-corrected pattern 22 are far apart, and the two truncated parts are not easily bridged due to their proximity, so as to effectively ensure the electrical isolation between the third subpattern 221 and the fourth subpattern 222. In other words, if only the vertical distance between two currently truncated parts is required to be kept unchanged and the vertical width of the preset region is desired to decrease, the horizontal length of the preset region may be increased. Conversely, if the horizontal length of the preset region is desired to decrease and the vertical distance between the two currently truncated parts is kept unchanged at the same time, the vertical width of the preset region may be increased. In the present embodiment, the horizontal length of the second orthographic projection is greater than or equal to twice the preset horizontal distance, and a minimum value of the first vertical width 234 is greater than or equal to 20 nm. At the same time, in order to prevent the influence of the trimming of the connection pattern 223 on the performance of other electrical components, a maximum value of the first vertical width 234 is further limited in the present embodiment according to positions of such electrical components.

The present application further provides a first film layer. The first film layer is located on one side of the to-be-corrected pattern 22 away from the trim mask. The to-be-corrected pattern 22 has a first connection hole 224 on a surface, which is configured to connect the first film layer. A first vertical distance 232 between the first connection hole 224 and the orthographic projection of the preset region is greater than or equal to a first preset interval. The first preset interval is 30 nm to 50 nm, for example, 35 nm, 40 nm or 45 nm.

In an optional embodiment, the present application further provides a second film layer. The second film layer is located between the to-be-corrected pattern 22 and the trim mask. The to-be-corrected pattern 22 has a second connection hole 225 on a surface, which is configured to connect the second film layer. A second vertical distance 233 between the second connection hole 225 and the orthographic projection of the preset region is greater than or equal to a second preset interval. The second preset interval is 35 nm to 55 nm, for example, 40 nm, 45 nm or 50 nm.

That is, in order to prevent the influence of the exposure process performed through the trim mask on electrical properties of the first connection hole 224 and the second connection hole 225, the maximum value of the first vertical width 234 is limited by a vertical width between the first connection hole 224 and the second connection hole 225, the first preset interval and the second preset interval. In addition, the influence of the exposure process on electrical properties of the third subpattern 221 and the fourth subpattern 222 may also be prevented. In this case, the maximum value of the first vertical width 234 is further limited by a vertical distance between the third subpattern 221 and the fourth subpattern 222; that is, the maximum value of the first vertical width 234 should be less than or equal to the vertical width of the connection pattern 223.

Referring to FIG. 13, in an optional embodiment, the preset region 23 is in a shape of a rectangle or a combination of plural rectangles. The preset region 23 is within the effective range 23b. Specifically, the preset region 23 includes a first rectangle 25 and a second rectangle 26. The first rectangle 25 is connected horizontally with the second rectangle 26. In the plane including the first pattern, an orthographic projection of the first rectangle 25 does not overlap with the first pattern, and an orthographic projection of the second rectangle 26 overlaps partially with the first subpattern 211.

In an optional embodiment, a vertical width of the first rectangle 25 may be equal or unequal to that of the second rectangle 26. When their vertical widths are unequal, a side of the first rectangle 25 facing the first connection hole 224 is flush with a side of the second rectangle 26 facing the first connection hole 224, or a side of the first rectangle 25 facing away from the first connection hole 224 is flush with a side of the second rectangle 26 facing away from the first connection hole 224, or sides are not misaligned. The adjustment of the vertical width and position of the second rectangle 26 may avoid a particular electrical component and prevent damages of the trim process to the particular electrical component.

In an optional embodiment, the preset region further includes a third rectangle. The third rectangle and the first rectangle are located on two opposite sides of the second rectangle. The third rectangle is concatenated with the second rectangle. A horizontal length of the third rectangle is equal or unequal to that of the first rectangle. A vertical width of the third rectangle is equal or unequal to that of the first rectangle. An axis of the third rectangle is symmetrical or asymmetrical with that of the first rectangle. The symmetry of the third rectangle with the first rectangle is related to a position of the second subpattern. When the connection pattern is trimmed, a position of the third rectangle may be adjusted according to the position of the second subpattern, so as to prevent the influence of the arrangement of the third rectangle on the performance of the second subpattern.

In an optional embodiment, the first rectangle 25 has a horizontal length of 55 nm to 85 nm, for example, 65 nm, 70 nm or 75 nm, and the first rectangle 25 has a vertical width of 20 nm to 50 nm, for example, 30 nm, 35 nm or 40 nm. The second rectangle 26 has a horizontal length of 20 nm to 50 nm, for example, 30 nm, 35 nm or 40 nm. A vertical width of the second rectangle 26 is equal to that of the first rectangle 25. The second rectangle 26 has a vertical width of 20 nm to 50 nm, for example, 30 nm, 35 nm or 40 nm.

Referring to FIG. 14 and FIG. 15 in an optional embodiment, after the trim mask is formed, the third positive photoresist layer 24 is exposed through the trim mask, and the exposed connection pattern 223 (refer to FIG. 10) is etched through a development process and a patterned etching process. A horizontal length of an actual trim region 23a corresponding to the trim mask is greater than that of the connection pattern 223. The connection pattern 223 can be effectively truncated by using the trim mask according to the present embodiment, which ensures effective electrical isolation between the third subpattern 221 and the fourth subpattern 222.

In an optional embodiment, the horizontal length of the second orthographic projection is greater than or equal to twice the preset horizontal distance, which helps accurately remove the to-be-corrected pattern overlapping with the orthographic projection of the preset region to form a target pattern meeting requirements in a case where a trim pattern corresponding to the preset region contracts.

Those of ordinary skill in the art may understand that the above embodiments are specific embodiments for implementing the present application. However, in practical applications, various changes in forms and details may be made thereto without departing from the spirit and scope of the present application. Any person skilled in the art can make respective changes and modifications without departing from the spirit and scope of the present application. Therefore, the protection scope of the present application should be subject to the scope defined by the claims.

What is claimed is:

1. An integrated circuit structure formation method, comprising:
providing a first pattern and a to-be-corrected pattern, the first pattern comprising a first subpattern and a second subpattern spaced apart, the to-be-corrected pattern being located between the first subpattern and the second subpattern, and a preset horizontal distance being provided between the first pattern and the to-be-corrected pattern;
providing a trim mask, the trim mask having a preset region, in a plane comprising the to-be-corrected pattern, a first orthographic projection of the preset region overlapping with the to-be-corrected pattern, and a second orthographic projection being located on one side of the to-be-corrected pattern and having a horizontal length greater than or equal to twice the preset horizontal distance; and
performing an exposure process through the trim mask to form a target pattern.

2. The integrated circuit structure formation method according to claim 1, wherein the preset region is in a shape of a rectangle or a combination of plural rectangles.

3. The integrated circuit structure formation method according to claim 2, wherein the preset region comprises a first rectangle and a second rectangle, the first rectangle being connected horizontally with the second rectangle; and
in a plane comprising the first pattern, an orthographic projection of the first rectangle does not overlap with the first pattern, and an orthographic projection of the second rectangle overlaps with the first pattern.

4. The integrated circuit structure formation method according to claim 3, wherein the first rectangle has a horizontal length of 55 nm to 85 nm.

5. The integrated circuit structure formation method according to claim 3, wherein the first rectangle has a vertical width of 20 nm to 50 nm.

6. The integrated circuit structure formation method according to claim 3, wherein the second rectangle has a horizontal length of 20 nm to 50 nm.

7. The integrated circuit structure formation method according to claim 3, wherein a vertical width of the second rectangle is equal to that of the first rectangle.

8. The integrated circuit structure formation method according to claim 3, wherein the second rectangle has a vertical width of 20 nm to 50 nm.

9. The integrated circuit structure formation method according to claim 7, wherein the second rectangle has the vertical width of 20 nm to 50 nm.

10. The integrated circuit structure formation method according to claim 1, further comprising: providing a first film layer, the first film layer being located on one side of the to-be-corrected pattern away from the trim mask;
the to-be-corrected pattern having a first connection hole on a surface configured to connect the first film layer, a first vertical distance between the first connection hole and an orthographic projection of the preset region being greater than or equal to a first preset interval.

11. The integrated circuit structure formation method according to claim 10, wherein the first preset interval is 30 nm to 50 nm.

12. The integrated circuit structure formation method according to claim 10, further comprising: providing a second film layer, the second film layer being located between the to-be-corrected pattern and the trim mask;
the to-be-corrected pattern having a second connection hole on the surface configured to connect the second film layer, a second vertical distance between the second connection hole and the orthographic projection of the preset region being greater than or equal to a second preset interval.

13. The integrated circuit structure formation method according to claim 12, wherein the second preset interval is 35 nm to 55 nm.

14. The integrated circuit structure formation method according to claim 1,
wherein the to-be-corrected pattern comprises a connection pattern configured to connect adjacent independent subpatterns, and a vertical width of the preset region is less than or equal to that of the connection pattern.

15. The integrated circuit structure formation method according to claim 1,
wherein the step of performing an exposure process comprises: exposing a positive photoresist layer or a negative photoresist layer through the trim mask.

16. The integrated circuit structure formation method according to claim 1, wherein the step of forming the first pattern comprises:
providing a first photomask, a substrate, and a target layer and a first positive photoresist layer sequentially stacked on a surface of the substrate, and performing the exposure process on the first positive photoresist layer through the first photomask; and
performing a development process to form a first photoetch pattern, the first photoetch pattern being configured to etch the target layer to form the first pattern.

17. The integrated circuit structure formation method according to claim 16, wherein the step of forming the to-be-corrected pattern comprises:
forming a second positive photoresist layer to fill the first photoetch pattern;
providing a second photomask, and performing the exposure process on the second positive photoresist layer through the second photomask; and
performing the development process to form a second photoetch pattern, the second photoetch pattern being configured to etch the target layer to form the to-be-corrected pattern.
